(19) United States
(12) Patent Application Publication
(10) Pub. No.: US 2026/0262473 A1
(43) Pub. Date: Sep. 3, 2026

(54) MEMBER FOR SEMICONDUCTOR MANUFACTURING APPARATUS

(71) Applicant: NGK Corporation, Nagoya-shi (JP)

(72) Inventors: Taro USAMI, Ginan-town (JP); Tatsuya KUNO, Nagoya-city (JP)

(21) Appl. No.: 19/657,103

(22) Filed: Apr. 24, 2026

Related U.S. Application Data
(63) Continuation of application No. PCT/JP2025/030848, filed on Sep. 2, 2025.

(30) Foreign Application Priority Data
Dec. 23, 2024 (JP) 2024-226658

(51) Int. Cl. H10P 72/72

(52) U.S. Cl. CPC H10P 72/722

(57) ABSTRACT

A member for semiconductor manufacturing apparatus includes a ceramic plate, plug placement holes and a plug. The plug has a gas flow path. The gas flow path has an upper gas flow path portion which proceeds obliquely upward and reaches an outlet. When a longitudinal section of a peripheral portion of the plug is viewed, a maximum length in an up-down direction between an open edge of the outlet and a bottom surface of the upper gas flow path portion is d1 [μm], a length in an up-down direction between an object support surface and an upper surface of the plug is dr [μm], a maximum length in an up-down direction, in a portion upstream of the upper gas flow path portion, of the gas flow path is d2 [μm], and D=d1+d2. The following are satisfied:

$$30 ≦ d 1 ≦ 100 , 10 ≦ dr ≦ 50 , 100 ≦ d 2 ≦ 200 and \vert d 2 - D \vert ≦ 50.$$

### CROSS-REFERENCE TO RELATED APPLICATION

This application is a continuation application of PCT/JP2025/030848, filed on Sep. 2, 2025, which claims the benefit of priority of Japanese Patent Application No. 2024-226658 filed on Dec. 23, 2024, the entire contents of which are incorporated herein by reference.

### BACKGROUND OF THE INVENTION

### 1. Field of the Invention

The present invention relates to a member for semiconductor manufacturing apparatus.

### 2. Description of the Related Art

Conventionally, as a member for semiconductor manufacturing apparatus, there is known one including a ceramic plate having a wafer placement portion on its upper surface and a plug arranged in a plug placement hole penetrating the ceramic plate in an up-down direction. For example, PTL 1 discloses, as a plug used for such a member for semiconductor manufacturing apparatus, one having a spiral gas flow path extending from an inlet provided in a lower surface of a plug body to an outlet provided in an upper surface thereof, the gas flow path being provided inside the plug body. According to FIG. 3 of PTL 1, the gas flow path has an upper gas flow path portion which proceeds obliquely upward from a position below the upper surface of the plug body and reaches the outlet provided in the upper surface of the plug body.

### CITATION LIST

### Patent Literature

PTL 1: JP2024-88883A

### SUMMARY OF THE INVENTION

However, in such a member for semiconductor manufacturing apparatus, it is necessary to provide a gap between the upper surface of the plug body and the lower surface of the wafer so that the plug does not lift the wafer from below, and therefore there is a problem that discharge may occur in a space including this gap and the outlet of the gas flow path. In addition, since the outlet peripheral portion of the upper gas flow path portion of the plug body is thin, chipping (breakage) tends to occur. When chipping occurs, the length in an up-down direction of the chipped portion increases, and therefore discharge is more likely to occur. Furthermore, when the gas flow path is too narrow, there is a problem that a gas flow rate cannot be ensured.

The present invention has been made in order to solve such problems, and a primary object thereof is to prevent the plug from lifting an object and, while ensuring a gas flow rate, to prevent occurrence of discharge in the vicinity of the outlet of the gas flow path.

[1]A member for semiconductor manufacturing apparatus of the present invention includes: a ceramic plate having an object support surface capable of supporting an object on its upper surface; a plug placement hole penetrating the ceramic plate in an up-down direction; and a plug arranged in the plug placement hole and having a gas flow path formed so as to extend from an inlet provided in a lower surface of a plug body to an outlet provided in an upper surface thereof, the member for semiconductor manufacturing apparatus being configured such that the gas flow path has an upper gas flow path portion which proceeds obliquely upward from a position below the upper surface of the plug body and reaches the outlet, and, when a longitudinal section around the plug is viewed, a maximum length in an up-down direction between an open edge of the outlet and a bottom surface of the upper gas flow path portion is d1 [μm], a length in an up-down direction between the object support surface and the upper surface of the plug is dr [μm], a maximum length in an up-down direction, in a portion upstream of the upper gas flow path portion, of the gas flow path is d2 [μm], and a sum of d1 and dr is D [μm], and the following expressions (1) to (4) are satisfied:

$$30 ≦ d 1 ≦ 100 \qquad ( 1 )$$

$$10 ≦ dr ≦ 50 \qquad ( 2 )$$

$$100 ≦ d 2 ≦ 200 \qquad ( 3 )$$

$$\vert d 2 - D \vert ≦ 50 \qquad ( 4 )$$

In this member for semiconductor manufacturing apparatus, the lengths d1, dr, d2 and D satisfy the expressions (1) to (4). Therefore, it is possible to prevent the plug from lifting the object and, while ensuring a gas flow rate, to prevent occurrence of discharge in the vicinity of the outlet of the gas flow path.

In this specification, the present invention may be described using terms such as up-down, left-right and front-rear, but these terms represent merely relative positional relationships. Accordingly, when an orientation of the member for semiconductor manufacturing apparatus is changed, the up-down direction may become the left-right direction, and the left-right direction may become the up-down direction. Even in such a case, it is within the technical scope of the present invention.

[2] In the member for semiconductor manufacturing apparatus of the present invention (the member for semiconductor manufacturing apparatus described in [1] above), the open edge of the outlet may have a chipping portion. Even when the open edge of the outlet of the gas flow path has a chipping portion in this way, it is possible to prevent occurrence of discharge.

[3] In the member for semiconductor manufacturing apparatus of the present invention (the member for semiconductor manufacturing apparatus described in [1] or [2] above), the gas flow path may be provided in a spiral shape. In this way, it is possible to further suppress discharge by increasing a creepage distance along the gas flow path and to make a flow of gas in the gas flow path smooth.

[4] In the member for semiconductor manufacturing apparatus of the present invention (the member for semiconductor manufacturing apparatus described in any one of [1] to [3] above), the object may be a wafer. In this way, it is possible to suppress occurrence of discharge on a lower surface side of the wafer.

[5] In the member for semiconductor manufacturing apparatus of the present invention (the member for semiconductor manufacturing apparatus described in any one of [1] to [3] above), the object may be a focus ring. Generally, a focus ring placement surface is formed one step lower than a wafer placement surface, and therefore a plug corresponding to the focus ring among plugs of the ceramic plate is shorter in length in an up-down direction than a plug corresponding to the wafer. Accordingly, in a gas flow path of the plug corresponding to the focus ring, a potential gradient becomes large and discharge is likely to occur. Therefore, significance of applying the present invention is high.

[6] The member for semiconductor manufacturing apparatus of the present invention (the member for semiconductor manufacturing apparatus described in any one of [1] to [5] above) may further comprise a conductive base member joined to a lower surface of the ceramic plate and provided with a gas supply path communicating with the plug placement hole. When the conductive base member is used as a plasma generation electrode, a high voltage is applied between the wafer and the conductive base member upon generation of plasma, and therefore a situation where discharge is le to occur arises in the vicinity of the outlet of the gas flow path of the plug. Accordingly, significance of applying the present invention is high.

[7] In the member for semiconductor manufacturing apparatus of the present invention (the member for semiconductor manufacturing apparatus described in any one of [1] to [6] above), the plug may have an internal space with at least one of an upper part or a lower part thereof closed. When the gas flow path is regarded as a dielectric of a capacitor in a longitudinal section of the plug, a voltage applied to the capacitor is considered to decrease as a relative permittivity of the entire plug decreases. When the plug has an internal space separate from the gas flow path, a relative permittivity of the entire plug becomes lower than in a case where such an internal space is not provided. Therefore, the voltage applied to the capacitor with the gas flow path as a dielectric decreases, and it is possible to suppress occurrence of discharge in the gas flow path.

### BRIEF DESCRIPTION OF THE DRAWINGS

FIG. 1 is a longitudinal sectional view of a wafer placement table 10.

FIG. 2 is a plan view of a ceramic plate 20.

FIG. 3 is a perspective view of a plug 50.

FIG. 4 is a longitudinal sectional view of the plug 50.

FIG. 5 is a partially enlarged view of FIG. 1 (a longitudinal sectional view of a peripheral portion of the plug 50).

FIG. 6 is a partially enlarged view of FIG. 1 (a longitudinal sectional view of a peripheral portion of the plug 50).

FIG. 7A is an explanatory diagram showing a virtual equivalent circuit of the plug 50.

FIG. 7B is a graph showing changes in voltage with respect to positions in an up-down direction inside the plug 50.

FIG. 8 is a longitudinal sectional view of a plug 50 according to another embodiment.

FIG. 9 is a longitudinal sectional view of a plug 50 according to another embodiment.

FIG. 10 is a plan view of a plug 50 according to another embodiment.

### DETAILED DESCRIPTION OF THE INVENTION

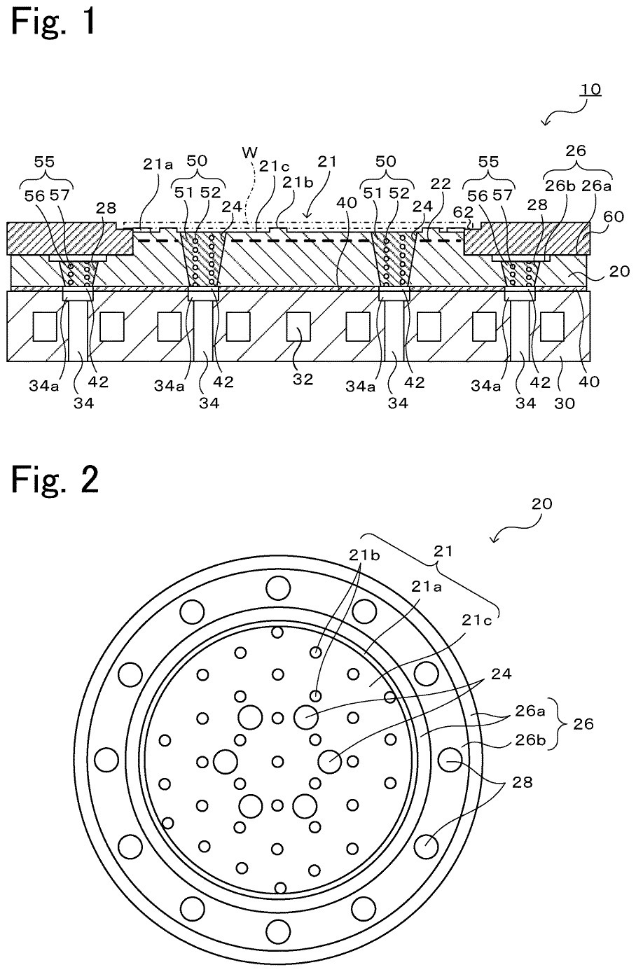

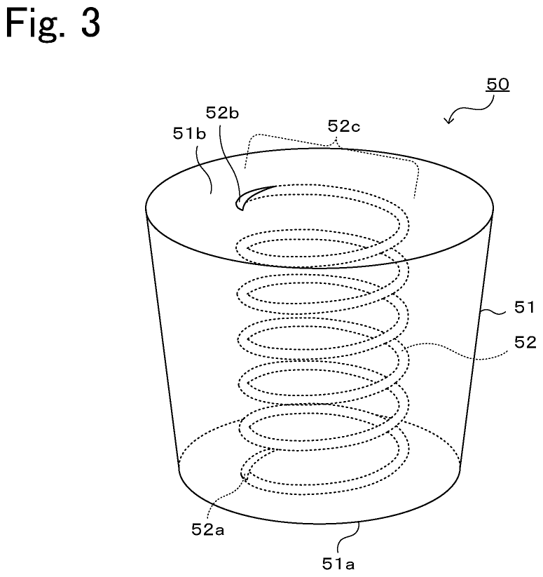

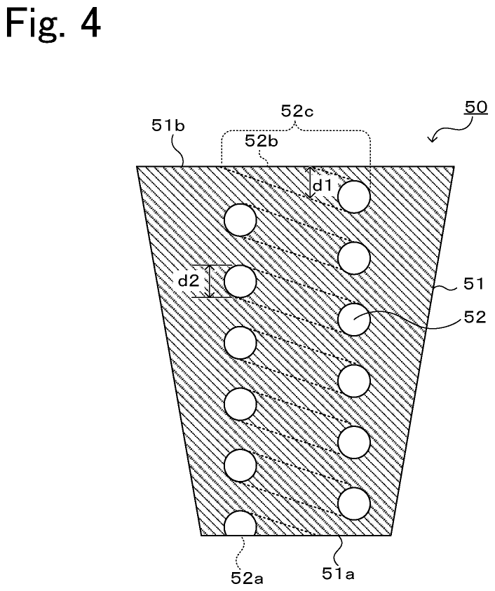

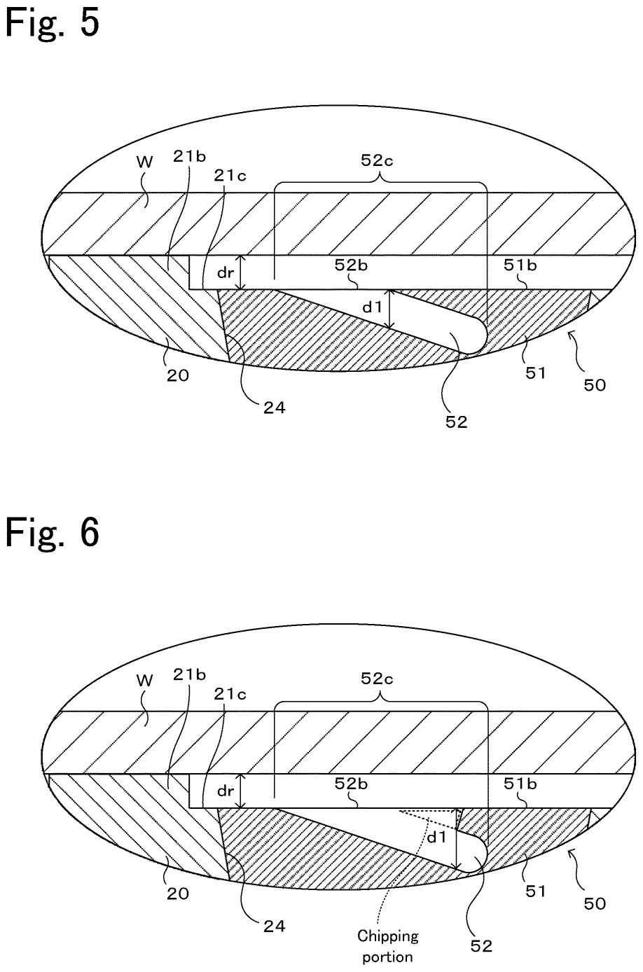

Preferred embodiments of the present invention will be described below with reference to the drawings. FIG. 1 is a longitudinal sectional view of a wafer placement table 10 which is an example of the member for semiconductor manufacturing apparatus of the present invention. FIG. 2 is a plan view of a ceramic plate 20. FIG. 3 is a perspective view of a plug 50. FIG. 4 is a longitudinal sectional view of the plug 50. FIGS. 5 and 6 are partially enlarged views of FIG. 1 (longitudinal sectional views of a peripheral portion of the plug 50). FIG. 5 shows an embodiment in which an open edge of an outlet 52b has no chipping portion, and FIG. 6 shows an embodiment in which an open edge of the outlet 52b has a chipping portion.

The wafer placement table 10 includes a ceramic plate 20, a base plate 30 and a metal bonding layer 40. Plug placement holes 24 and plug placement holes 28 are provided in the ceramic plate 20. A plug 50 is arranged in each plug placement hole 24, and a plug 55 is arranged in each plug placement hole 28.

The ceramic plate 20 is a ceramic disk (for example, a disk having a diameter of 300 mm) such as an alumina sintered body or an aluminum nitride sintered body. The thickness of the ceramic plate 20 is, for example, 1 mm or more and 5 mm or less. The ceramic plate 20 has, on its upper surface, a wafer placement surface 21 and a focus ring (FR) placement surface 26. The wafer placement surface 21 is a circular surface on which a wafer W is placed. As shown in FIG. 2, a seal band 21a is formed along an outer edge of the wafer placement surface 21, and a plurality of small circular projections 21b are formed over the whole surface thereof. The seal band 21a and the small circular projections 21b have the same height, and this height is, for example, several μm to several tens of μm. A portion of the wafer placement surface 21 where the seal band 21a and the small circular projections 21b are not provided is referred to as a reference surface 21c. The FR placement surface 26 is an annular surface provided around the wafer placement surface 21. A height of the FR placement surface 26 is one step lower than a height of the wafer placement surface 21. As shown in FIG. 2, an FR support surface 26a and an annular recessed portion 26b are formed in the FR placement surface 26. A bottom surface of the recessed portion 26b is one step lower than the FR support surface 26a. An annular focus ring 60 is placed on the FR placement surface 26 in a state of being in contact with the FR support surface 26a. The focus ring 60 is formed of, for example, Si. Above an inner side surface of the focus ring 60, a circumferential groove 62 is provided so as not to contact the wafer W. An outer diameter of the focus ring 60 is larger than an outer diameter of the ceramic plate 20. Therefore, the focus ring 60 is placed on the FR placement surface 26 in a state of protruding (overhanging) to an outside of the wafer placement table 10. The ceramic plate 20 incorporates an electrode 22. The electrode 22 is a planar mesh electrode used as an electrostatic electrode, and a DC voltage can be applied thereto. When a DC voltage is applied to the electrode 22, the wafer W is attracted and fixed to the wafer placement surface 21 (specifically, an upper surface of the seal band 21a and an upper surface of the small circular projections 21b) by an electrostatic attractive force, and when application of the DC voltage is stopped, attraction and fixation of the wafer W to the wafer placement surface 21 are released. The wafer W is an example of the object of the present invention, and a top surface of the seal band 21a and a top surface of the small circular projections 21b of the wafer placement surface 21 are examples of the object support surface of the present invention. The focus ring 60 is also an example of the object of the present invention, and the FR support surface 26a of the FR placement surface 26 is an example of the object support surface of the present invention.

Each plug placement hole 24 is a hole penetrating the ceramic plate 20 in an up-down direction and is a through-hole extending from a lower surface of the ceramic plate 20 to the reference surface 21c of the wafer placement surface 21. Each plug placement hole 24 faces a gas hole (gas supply path) 34 of the base plate 30. Each plug placement hole 24 penetrates the electrode 22 in the up-down direction, but the electrode 22 is not exposed to an inner peripheral surface of the plug placement hole 24. Each plug placement hole 24 is a tapered hole having a truncated cone space which is narrower on a lower side. As shown in FIG. 2, the plug placement holes 24 are provided at a plurality of positions (for example, a plurality of positions at equal intervals in a circumferential direction) so as to open to the reference surface 21c of the wafer placement surface 21 of the ceramic plate 20.

Each plug placement hole 28 is a hole penetrating the ceramic plate 20 in an up-down direction and is a through-hole extending from the lower surface of the ceramic plate 20 to the bottom surface of the recessed portion 26b of the FR placement surface 26. Each plug placement hole 28 faces the gas hole 34 of the base plate 30. Each plug placement hole 28 is a tapered hole having a truncated cone space which is narrower on a lower side. As shown in FIG. 2, the plug placement holes 28 are provided at a plurality of positions (for example, a plurality of positions at equal intervals in the circumferential direction) so as to open to the bottom surface of the recessed portion 26b of the FR placement surface 26 of the ceramic plate 20.

The base plate 30 is an example of the conductive base member, and is a conductive disk having good thermal conductivity (a disk having the same diameter as, or a larger diameter than, the ceramic plate 20). Inside the base plate 30, a refrigerant flow path 32 in which a refrigerant (for example, an electrically insulating liquid such as a fluorine-based inert liquid) circulates and gas holes 34 which supply gas to the plugs 50 and 55 are formed. The gas holes 34 are provided so as to penetrate the base plate 30 in an up-down direction and have large-diameter portions 34a on an upper side. In plan view, each large-diameter portion 34a includes a lower opening of a plug placement hole 24. The refrigerant flow path 32 is formed, in plan view, over an entire surface of the base plate 30 from an inlet to an outlet in a one-stroke pattern. As a material for the base plate 30, for example, metal or a composite material is used. Examples of the metal include Mo. Examples of the composite material include composite materials of metal and ceramic. Examples of the composite material of metal and ceramic include a metal matrix composite (MMC) and a ceramic matrix composite (CMC). Specific examples of such composite materials include a material containing Si, SiC and Ti, and a material obtained by impregnating a SiC porous body with Al and/or Si. A material containing Si, SiC and Ti is referred to as SiSiCTi, a material obtained by impregnating a SiC porous body with Al is referred to as AlSiC, and a material obtained by impregnating a SiC porous body with Si is referred to as SiSiC. As the material for the base plate 30, it is preferable to select one whose coefficient of thermal expansion is close to that of the material of the ceramic plate 20. The base plate 30 is also used as an RF electrode. Specifically, an upper electrode (not shown) is disposed above the wafer placement surface 21, and when high-frequency power is applied between parallel plate electrodes including the upper electrode and the base plate 30, plasma is generated.

The metal bonding layer 40 joins the lower surface of the ceramic plate 20 and an upper surface of the base plate 30. The metal bonding layer 40 is formed by, for example, TCB (Thermal Compression Bonding). TCB is a known method in which a metal bonding material is sandwiched between two members to be bonded, and the two members are bonded together under pressure while being heated to a temperature equal to or lower than a solidus temperature of the metal bonding material. The metal bonding layer 40 may be a layer formed of solder or a metal brazing material. The metal bonding layer 40 has through-holes 42. The through-holes 42 are provided at positions facing the large-diameter portions 34a of the gas holes 34. The through-holes 42 are provided coaxially with the large-diameter portions 34a, and a diameter of each through-hole 42 is equal to a diameter of the corresponding large-diameter portion 34a. In the present specification, “coaxial” includes not only a perfectly coaxial case but also a substantially coaxial case (for example, a case within a tolerance range), and the same applies hereinafter. In the present specification, “equal” includes not only a perfectly equal case but also a substantially equal case (for example, a case within a tolerance range), and the same applies hereinafter.

The plug 50 is arranged in the plug placement hole 24. The plug 50 may be bonded to the plug placement hole 24 by an adhesive or the like, may be fitted therein, or may be threaded therein. The plug 50 has a plug body 51 and a gas flow path 52 formed inside the plug body 51. The plug body 51 is a dense electrically insulating member and is formed of, for example, the same material (such as alumina or aluminum nitride) as the ceramic plate 20. The plug body 51 is a member having a truncated cone shape which is narrower on a lower side. The dense member may have a porosity of 5% or less (preferably 3% or less, more preferably 1% or less). An upper surface 51b of the plug body 51 is positioned below a lower surface of the wafer W (for example, in the same plane as the reference surface 21c). The lower surface of the wafer W coincides with wafer support surfaces (top surfaces) of the seal band 21a and the small circular projections 21b. The gas flow path 52 is formed so as to extend from an inlet 52a provided in a lower surface 51a of the plug body 51 to an outlet 52b provided in the upper surface 51b of the plug body 51. Here, the gas flow path 52 is formed in a spiral shape. The gas flow path 52 has an upper gas flow path portion 52c which proceeds obliquely upward from a position below the upper surface 51b of the plug body 51 and reaches the outlet 52b.

When the plug 50 is viewed in longitudinal section, a maximum length in an up-down direction between the open edge of the outlet 52b and the bottom surface of the upper gas flow path portion 52c is d1 [μm](see FIG. 5); a length in an up-down direction between the wafer support surface (the top surface of the seal band 21a and the top surface of the small circular projections 21b) and the upper surface 51b of the plug body 51 is dr [μm](see FIG. 5); a maximum length in an up-down direction, in a portion upstream of the upper gas flow path portion 52c, of the gas flow path 52 is d2 [μm](see FIG. 4); and a sum of d1 and dr is D [μm]. These lengths d1, dr, d2 and D satisfy the following expressions (1) to (4). When the open edge of the outlet 52b has a chipping portion (chipped portion), the length d1 is as shown in FIG. 6. When these expressions (1) to (4) are satisfied, as in the examples described later, it is possible to prevent the plugs 50 and 55 from lifting objects (the wafer W and the focus ring 60) and, while ensuring a gas flow rate, to prevent occurrence of discharge in the vicinity of the outlets of the gas flow paths 52 and 57.

$$30 ≦ d 1 ≦ 100 \qquad ( 1 )$$

$$10 ≦ dr ≦ 50 \qquad ( 2 )$$

$$100 ≦ d 2 ≦ 200 \qquad ( 3 )$$

$$\vert d 2 - D \vert ≦ 50 \qquad ( 4 )$$

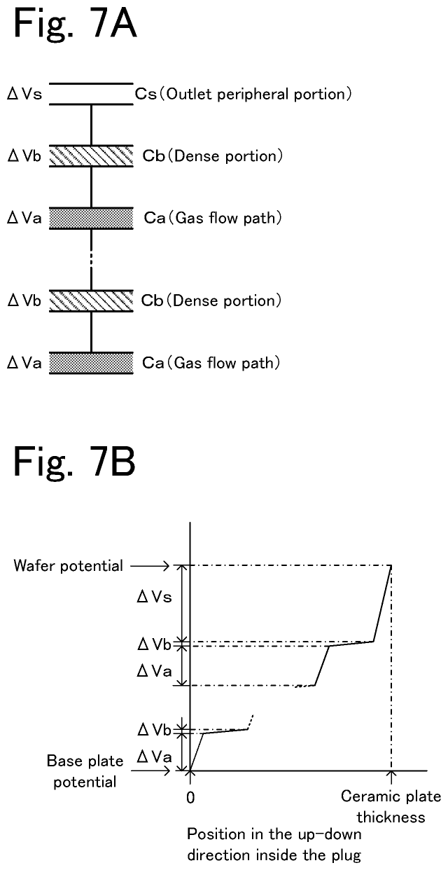

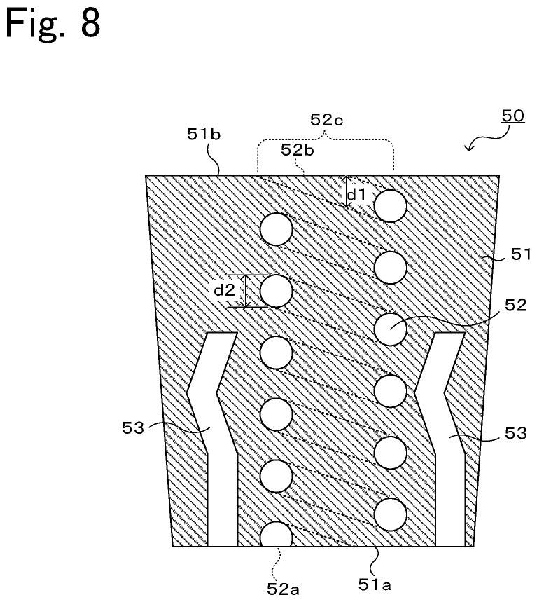

FIG. 7A shows a virtual equivalent circuit obtained by regarding, as dielectrics of capacitors, each of a plurality of gas flow paths 52 appearing in a longitudinal section of the plug 50 and each portion of the plug body 51 (dense portion) between the gas flow paths 52. In this virtual equivalent circuit, between the base plate 30 and the wafer W, capacitors Ca, each obtained by regarding the gas flow path 52 as a dielectric, and capacitors Cb, each obtained by regarding the dense portion as a dielectric, are alternately connected in series, and at a position closest to the wafer W, a capacitor Cs is connected. The capacitor Cs is obtained by regarding, as a dielectric, a sum (outlet peripheral portion) of a space of the outlet 52b of the gas flow path 52 and a space between the wafer support surface and the upper surface 51b of the plug body 51. ΔVa is a voltage applied to the capacitor Ca, ΔVb is a voltage applied to the capacitor Cb, and AVs is a voltage applied to the capacitor Cs. Generally, since a relative permittivity (for example, a relative permittivity of helium) of the gas flow path 52 is significantly smaller than a relative permittivity of the plug body 51, which is a dense portion, an electrostatic capacitance of the capacitor Ca becomes significantly smaller than an electrostatic capacitance of the capacitor Cb. Therefore, ΔVa becomes significantly larger than ΔVb. In addition, generally, a length in an up-down direction of the outlet peripheral portion is larger than a length in an up-down direction of the gas flow path 52, and therefore an electrostatic capacitance of the capacitor Cs becomes smaller than that of the capacitor Ca. Therefore, ΔVs becomes larger than ΔVa. FIG. 7B shows changes in voltage with respect to positions in the up-down direction inside the plug 50 in such a virtual equivalent circuit. Since ΔVs is larger than ΔVa, it can be said that an environment in which discharge is likely to occur is formed in the outlet peripheral portion of the gas flow path 52.

The plug 55 is arranged in the plug placement hole 28. The plug 55 may be bonded to the plug placement hole 28 by an adhesive or the like, may be fitted therein, or may be threaded therein. The plug 55 has a plug body 56 and a gas flow path 57 formed inside the plug body 56. Since the plug body 56 and the gas flow path 57 are generally the same as the plug body 51 and the gas flow path 52, respectively, only differences therefrom will be described below. An upper surface of the plug body 56 is positioned below a lower surface of the focus ring 60 (for example, in the same plane as the bottom surface of the recessed portion 26b). The lower surface of the focus ring 60 coincides with the FR support surface 26a. Similarly to the gas flow path 52, the gas flow path 57 has an upper gas flow path portion. The lengths d1 and d2 are defined as described above. Here, the length dr is a length in an up-down direction between the lower surface of the focus ring 60 (top surface of the FR support surface 26a) and the upper surface of the plug body 56. The lengths d1, dr, d2 and D for the plug 55 also satisfy the above expressions (1) to (4).

Next, an example of use of the wafer placement table 10 configured as described above will be explained. First, in a state where the wafer placement table 10 is installed in an unillustrated chamber, the focus ring 60 is placed on the FR placement surface 26, and the wafer W is placed on the wafer placement surface 21. Then, the inside of the chamber is evacuated by a vacuum pump to adjust the pressure to a predetermined degree of vacuum, and a DC voltage is applied to the electrode 22 of the ceramic plate 20 to generate an electrostatic attractive force, thereby attracting and fixing the wafer W to the wafer placement surface 21 (specifically, to the upper surface of the seal band 21a and the upper surfaces of the small circular projections 21b). Next, the inside of the chamber is set to a reactive gas atmosphere having a predetermined pressure (for example, several tens to several hundreds of Pa), and in this state, a high-frequency voltage is applied between an unillustrated upper electrode provided in a ceiling portion of the chamber and the base plate 30 of the wafer placement table 10 to generate plasma. A surface of the wafer W is processed by the generated plasma. A refrigerant is circulated in the refrigerant flow path 32 of the base plate 30. Backside gas is introduced into the gas holes 34 from an unillustrated gas cylinder. As the backside gas, a heat transfer gas (for example, helium) is used. The backside gas passes through the gas holes 34, the through-holes 42 and the plugs 50 and is supplied and sealed into a space between a rear surface of the wafer W and the reference surface 21c of the wafer placement surface 21. The backside gas also passes through the gas holes 34, the through-holes 42 and the plugs 55 and is supplied and sealed into a space between a rear surface of the focus ring 60 and the recessed portion 26b of the FR placement surface 26. Due to the presence of this backside gas, heat conduction between the wafer W and the ceramic plate 20 and heat conduction between the focus ring 60 and the ceramic plate 20 are efficiently performed. Further, due to the presence of the electrically insulating plugs 50 and 55 disposed in the plug placement holes 24 and 28, respectively, a creepage distance between the wafer W and the base plate 30 and a creepage distance between the focus ring 60 and the base plate 30 are increased, and so on, and therefore it is possible to suppress occurrence of discharge in the plug placement holes 24 and 28.

Next, an example of a method for manufacturing the plug 50 will be described. First, a molded body that becomes the plug 50 after firing is produced. Dimensions of the molded body are determined on the basis of dimensions of the plug 50 in consideration of shrinkage upon firing. In producing the molded body, a mold having a molding space of the same shape as that of the molded body is produced by, for example, a 3D printer, and the molded body is formed in the mold. The molded body can be formed by, for example, mold casting. In mold casting, a ceramic slurry containing a ceramic powder, a solvent, a dispersant and a gelling agent is poured into the molding space of the mold, and the ceramic slurry is gelled by chemically reacting the gelling agent, thereby forming the molded body in the mold. Then, the mold is removed by causing the mold to disappear from an integral body in which the mold and the molded body are integrated, thereby obtaining the molded body. When a material having a melting point (when the melting point is represented as a temperature range, an upper limit thereof) equal to or lower than a drying temperature of the molded body is used as a material of the mold, it is possible to melt and remove the mold at the drying temperature when drying the molded body. For example, when wax melting at 70° C. is used as the material of the mold, the mold can be melted and removed at the time of drying the molded body at 80° C., thereby obtaining the molded body. Then, the molded body is degreased, and then fired, thereby producing the plug 50. A degreasing temperature and a firing temperature (maximum reached temperature) may be set as appropriate in consideration of a sintering temperature of the ceramic powder contained in the molded body. A degreasing atmosphere and a firing atmosphere may be appropriately selected from an air atmosphere, an inert gas atmosphere, a vacuum atmosphere, a hydrogen atmosphere and the like. The plug 55 can also be manufactured in the same manner.

According to the wafer placement table 10 described above in detail, the lengths d1, dr, d2 and D for the plug 50 satisfy the above expressions (1) to (4). The lengths d1, dr, d2 and D for the plug 55 also satisfy the above expressions (1) to (4). Therefore, it is possible to prevent the plugs 50 and 55 from lifting objects (the wafer W and the focus ring 60) and, while ensuring a gas flow rate, to prevent occurrence of discharge in the vicinity of the outlets of the gas flow paths 52 and 57.

The open edge of the outlet 52b of the gas flow path 52 may have a chipping portion. Even when the open edge of the outlet 52b of the gas flow path 52 has a chipping portion in this way, it is possible to prevent occurrence of discharge. The same applies to an outlet of the gas flow path 57.

Furthermore, the gas flow paths 52 and 57 are provided in a spiral shape. Therefore, it is possible to further suppress discharge by increasing the creepage distance along the gas flow paths 52 and 57, and also to make a flow of gas in the gas flow paths 52 and 57 smooth.

Still further, in the above-described embodiment, it is possible to suppress occurrence of discharge on the lower surface side of the wafer W and on the lower surface side of the focus ring 60. Generally, since the FR placement surface 26 is formed one step lower than the wafer placement surface 21, the plug 55 corresponding to the focus ring 60 among plugs of the ceramic plate 20 is shorter in length in an up-down direction than the plug 50 corresponding to the wafer W. Accordingly, in the gas flow path 57 of the plug 55, a potential gradient becomes large and discharge is likely to occur. Therefore, significance of applying the present invention is high.

In addition, the wafer placement table 10 has the base plate 30 (conductive base member) which is also used as a plasma generation electrode. Upon processing the wafer W with plasma, a high voltage is applied between the wafer W and the base plate 30, and therefore a situation where discharge is likely to occur arises in the vicinity of the outlets of the gas flow paths 52 and 57 of the plugs 50 and 55. Accordingly, significance of applying the present invention is high.

It should be noted that the present invention is not limited to the embodiment described above in any way, and it is needless to say that the present invention can be carried out in various modes as long as they fall within the technical scope of the present invention.

For example, in the above-described embodiment, one spiral gas flow path 52 is formed in the plug body 51 of the plug 50, but an internal space with at least one of an upper part or a lower part thereof closed may be provided separately from the gas flow path 52. The same applies to the plug 55. For example, as shown in FIG. 8, the plug 50 may have an internal space 53 whose upper part is closed and whose lower part is open. In FIG. 8, the same reference numerals are given to configurations identical to those of the above-described embodiment. When, in a longitudinal section of the plug 50, the gas flow path 52 is regarded as a dielectric of a capacitor, a voltage applied to the capacitor decreases as a relative permittivity of the entire plug decreases. When the plug 50 has the internal space 53 in addition to the gas flow path 52, a relative permittivity of the entire plug becomes lower than in a case where such an internal space 53 is not provided. Therefore, a voltage applied to the capacitor, with the gas flow path 52 being regarded as a dielectric thereof, decreases, and it is possible to suppress occurrence of discharge in the gas flow path 52. Instead of the internal space 53, an internal space whose upper part and lower part are both closed may be adopted. Alternatively, an internal space whose upper part is open and whose lower part is closed may be adopted. However, since an internal space whose upper part is open has a risk that chipping occurs at an open edge of the upper part, it is preferable that the internal space be one whose upper part is closed.

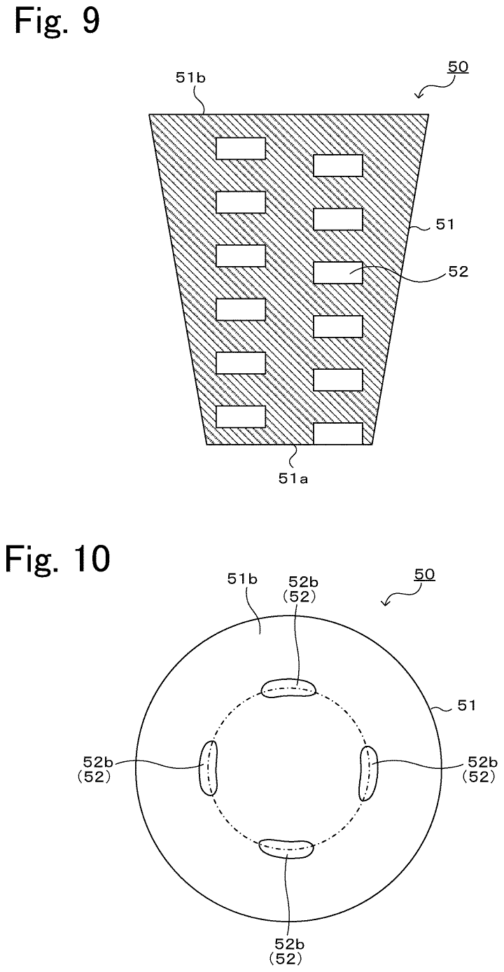

In the above-described embodiment, the cross-section of the gas flow path 52 of the plug 50 is circular, but the present invention is not particularly limited thereto, and, for example, the cross-section of the gas flow path 52 may be rectangular (see FIG. 9) or elliptical. In FIG. 9, the same reference numerals are given to configurations identical to those of the above-described embodiment. In FIG. 9, upper and lower sides of the rectangle may have a curved shape. The same applies to the plug 55.

In the above-described embodiment, one spiral gas flow path 52 is formed in the plug body 51, but the present invention is not particularly limited thereto, and a plurality of spiral gas flow paths 52 may be formed in the plug body 51. In this way, it is possible to increase an amount of gas that can be supplied. For example, as shown in FIG. 10, when the plug 50 is viewed in plan, outlets 52b of a plurality of (four, in this example) spiral gas flow paths 52 may be provided at equal intervals so as to form a concentric circle with the upper surface 51b of the plug body 51. The gas flow paths 52 are independent of each other without intersecting each other. In FIG. 10, the same reference numerals are given to configurations identical to those of the above-described embodiment. In FIG. 10, only some (for example, one) of the plurality of outlets 52b may be opened and the remaining outlets may be closed. In this way, in the gas flow paths 52 whose outlets 52b are closed, chipping does not occur at the open edge of the outlets 52b, and the same effects as the internal space 53 described above can be obtained. The same applies to the plug 55.

In the above-described embodiment, the gas flow path 52 is spiral, but the present invention is not particularly limited thereto, and, for example, the gas flow path 52 may be zigzag. The same applies to the plug 55.

In the above-described embodiment, the upper surface of the plug 50 is set to be in the same plane as the reference surface 21c of the wafer placement surface 21, but the present invention is not limited thereto, and it is only necessary that the upper surface be positioned lower than the wafer support surface (the top surface of the seal band 21a and the top surfaces of the small circular projections 21b). In addition, in the above-described embodiment, the upper surface of the plug 55 is set to be in the same plane as the bottom surface of the recessed portion 26b of the FR placement surface 26, but the present invention is not limited thereto, and it is only necessary that the upper surface be positioned lower than the FR support surface 26a.

In the above-described embodiment, the plugs 50 and 55 have a truncated cone shape which is narrower on a lower side, but the present invention is not limited thereto, and, for example, a cylindrical shape or a truncated cone shape which is narrower on an upper side may be adopted.

In the above-described embodiment, the FR placement surface 26 is described as having the annular recessed portion 26b, but the recessed portion 26b does not need to be annular, and for example may be a circular recessed portion disposed coaxially with the plug placement hole 28 and having a diameter larger than that of the plug placement hole 28. Further, the FR placement surface 26 does not need to have the recessed portion 26b.

In the above-described embodiment, as an example of the member for semiconductor manufacturing apparatus of the present invention, the wafer placement table 10 having the wafer placement surface 21 and the FR placement surface 26 has been described, but the wafer placement table 10 does not need to have the FR placement surface 26. Further, the member for semiconductor manufacturing apparatus of the present invention may be a focus ring placement table having the FR placement surface 26 and not having a wafer placement surface.

In the above-described embodiment, the wafer placement surface 21 is described as having the seal band 21a and the small circular projections 21b, but the seal band 21a and the small circular projections 21b do not need to be formed. The wafer placement surface 21 may be, for example, a flat surface.

In the above-described embodiment, the electrode 22 is described as being disposed at a position corresponding to the wafer placement surface 21, but the electrode 22 may instead of or in addition thereto be disposed at a position corresponding to the FR placement surface 26.

In the above-described embodiment, the electrode 22 incorporated in the ceramic plate 20 is exemplified as the electrostatic electrode, but the present invention is not particularly limited thereto. For example, instead of or in addition to the electrode 22, a heater electrode (resistance heating element) may be incorporated in the ceramic plate 20, or an RF electrode may be incorporated therein.

In the above-described embodiment, the ceramic plate 20 and the base plate 30 are joined by the metal bonding layer 40, but a resin adhesive layer may be used instead of the metal bonding layer 40.

In the above-described embodiment, a plurality of gas holes 34 forming the gas supply path are independently provided in the base plate 30, but the present invention is not particularly limited thereto. For example, the gas hole 34 may have one or a plurality of introduction portions for introducing gas from a rear surface of the base plate 30, and from the introduction portion, branches may be provided to open at positions facing the plug placement holes 24 and 28. In this way, it is possible to reduce a number of external gas pipes connected to the lower surface of the base plate 30 to a number smaller than the numbers of the plugs 50 and 55.

### EXAMPLES

Examples of the present invention will be described below. It should be noted that the following examples do not limit the present invention in any way.

With respect to the wafer mounting table 10 of the above-described embodiment, various samples having the same configuration were fabricated except that the lengths d1, dr, d2 and D shown in FIGS. 4 to 6 were set to the dimensions shown in Table 1, and discharge evaluation tests were conducted on these samples. The ceramic plate 20 and the plug 50 were made of alumina. In the discharge evaluation test, it was examined whether discharge occurred under a condition in which a potential difference of 2.7 kV was applied between the wafer W and the base plate 30. The results are shown in Table 1. In the column “Discharge evaluation,” “o” indicates no discharge, and “x” indicates discharge. In Examples 1, 5 and 6, the outlet open edge had no chipping portion, and in Examples 2, 3, 4 and 7, the outlet open edge had a chipping portion.

TABLE 1

| | Comparative Examples | | | | | | | | Examples | | | | | | |
|---|---|---|---|---|---|---|---|---|---|---|---|---|---|---|---|
| | 1 | 2 | 3 | 4 | 5 | 6 | 7 | 8 | 1 | 2 | 3 | 4 | 5 | 6 | 7 |
| d1 | 100 | 100 | 80 | 100 | 150 | 20 | 20 | 130 | 70 | 100 | 100 | 100 | 80 | 50 | 100 |
| dr | 0 | 80 | 50 | 50 | 50 | 50 | 50 | 50 | 50 | 10 | 30 | 50 | 30 | 30 | 50 |
| D(=d1 + dr) | 100 | 180 | 130 | 150 | 200 | 70 | 70 | 180 | 120 | 110 | 130 | 150 | 110 | 80 | 150 |
| d2 | 120 | 120 | 250 | 80 | 120 | 100 | 120 | 120 | 120 | 120 | 120 | 120 | 100 | 120 | 200 |
| d2-D | 20 | −60 | 120 | −70 | −80 | 30 | 50 | −60 | 0 | 10 | −10 | −30 | −10 | 40 | 50 |
| Discharge | ○ | x | x | x | x | ○ | ○ | x | ○ | ○ | ○ | ○ | ○ | ○ | ○ |
| Evaluation | | | | | | | | | | | | | | | |

In Examples 1 to 7, the above expressions (1) to (4) were satisfied. In any of Examples 1 to 7, discharge did not occur in the discharge evaluation test. In addition, the plug 50 did not lift the wafer W, and a gas flow rate of gas supplied from the gas flow path 52 was sufficient.

On the other hand, in Comparative Example 1, the expressions (1), (3) and (4) above were satisfied, but the expression (2) was not satisfied. Therefore, in the discharge evaluation test, discharge did not occur and the gas flow rate of gas supplied from the gas flow path 52 was sufficient, but the plug 50 sometimes lifted the wafer W. In Comparative Examples 6 and 7, the expressions (2) to (4) above were satisfied, but the expression (1) was not satisfied. Therefore, in the discharge evaluation test, discharge did not occur and the plug 50 did not lift the wafer W, but the gas flow rate of gas supplied from the gas flow path 52 was insufficient. In Comparative Examples 2 to 5 and 8, at least the expression (4) above was not satisfied, and therefore discharge occurred in the discharge evaluation test. In Comparative Example 3, since the length d2 was too long, discharge occurred in the gas flow path 52. In Comparative Example 4, since the length d2 was too short, the gas flow rate was insufficient. It is preferable that, in addition to the expressions (1) to (4), 80≤D≤150 be satisfied.

What is claimed is:

1. A member for semiconductor manufacturing apparatus comprising:
a ceramic plate having an object support surface capable of supporting an object on its upper surface;
a plug placement hole penetrating the ceramic plate in an up-down direction; and
a plug arranged in the plug placement hole and having a gas flow path formed so as to extend from an inlet provided in a lower surface of a plug body to an outlet provided in an upper surface thereof,
wherein the gas flow path has an upper gas flow path portion which proceeds obliquely upward from a position below the upper surface of the plug body and reaches the outlet, and,
when a longitudinal section around the plug is viewed, a maximum length in an up-down direction between an open edge of the outlet and a bottom surface of the upper gas flow path portion is d1 [μm], a length in an up-down direction between the object support surface and an upper surface of the plug is dr [μm], a maximum length in an up-down direction, in a portion upstream of the upper gas flow path portion, of the gas flow path is d2 [μm], and a sum of d1 and dr is D [μm],
the member for semiconductor manufacturing apparatus satisfying:
$$30 ≦ d 1 ≦ 100 \qquad ( 1 )$$
$$10 ≦ dr ≦ 50 \qquad ( 2 )$$
$$100 ≦ d 2 ≦ 200 \qquad ( 3 )$$
$$\vert d 2 - D \vert ≦ 50. \qquad ( 4 )$$

2. The member for semiconductor manufacturing apparatus according to claim 1,
wherein the open edge of the outlet has a chipping portion.

3. The member for semiconductor manufacturing apparatus according to claim 1,
wherein the gas flow path is provided in a spiral shape.

4. The member for semiconductor manufacturing apparatus according to claim 1,
wherein the object is a wafer.

5. The member for semiconductor manufacturing apparatus according to claim 1,
wherein the object is a focus ring.

6. The member for semiconductor manufacturing apparatus according to claim 1,
further comprising a conductive base member joined to a lower surface of the ceramic plate and provided with a gas supply path communicating with the plug placement hole.

7. The member for semiconductor manufacturing apparatus according to claim 1,
wherein the plug has an internal space with at least one of an upper part or a lower part thereof closed.
